(19) United States
(12) Patent Application Publication
(10) Pub. No.: US 2023/0008531 A1
(43) Pub. Date: Jan. 12, 2023

(54) FILTER CONTROL METHOD AND FILTER CONTROL DEVICE

(71) Applicant: Yamaha Corporation, Hamamatsu (JP)

(72) Inventors: Satoshi SENDO, Hamamatsu (JP); Kenji ISHIZUKA, Hamamatsu (JP)

(21) Appl. No.: 17/946,887

(22) Filed: Sep. 16, 2022

Related U.S. Application Data
(63) Continuation of application No. PCT/JP2021/008923, filed on Mar. 8, 2021.

(30) Foreign Application Priority Data
Mar. 18, 2020 (JP) 2020-047176

(51) Int. Cl. H04R 3/04; G06F 3/16; H03H 17/06

(52) U.S. Cl. CPC H04R 3/04; G06F 3/162; G06F 3/165; G06F 3/167; H03H 17/06; H04R 2499/15

(57) ABSTRACT

A filter control method controls a filter that controls frequency characteristics of a sound signal over a plurality of bands. The filter control method is implemented by a computer. The filter control method includes accepting a specifying operation from a user to specify a latency of the filter as a desired latency of the filter, accepting a setting operation from the user to set desired values of two or more parameters, which include phase characteristics and gain, for a respective band among the plurality of bands within a limit range determined based on the desired latency, and generating coefficients for the filter based on the desired values of the two or more parameters for the respective band.

### CROSS-REFERENCE TO RELATED APPLICATIONS

This application is a continuation application of International Application No. PCT/JP2021/008923. filed on Mar. 8, 2021, which claims priority to Japanese Patent Application No. 2020-047176 filed in Japan on Mar. 18, 2020. The entire disclosures of International Application No. PCT/JP2021/008923 and Japanese Patent Application No. 2020-047176 are hereby incorporated herein by reference.

### BACKGROUND

### Technological Field

One embodiment of the present invention relates to a filter control method and filter control device.

### Background Information

Japanese Laid-Open Patent Publication No. Hei 7-46687 discloses an FIR filter that applies minimum-phase characteristics to a low-frequency band and a linear phase to a high-frequency band. The FIR filter of Japanese Laid-Open Patent Publication No. Hei 7-46687 changes from the minimum phase to the linear phase in the intermediate band.

### SUMMARY

With the linear phase, filter latency becomes a problem. In particular, latency poses strong constraints when real-time operations are required, such as for live performances or speech.

Thus, one object of one embodiment of this disclosure is to provide a filter control method and a filter control device with which the values of the parameters can be adjusted within an acceptable latency range.

A filter control method controls a filter that controls frequency characteristics of a sound signal over a plurality of bands. The filter control method is implemented by a computer. The filter control method comprises accepting a specifying operation from a user to specify a latency of the filter as a desired latency of the filter, accepting a setting operation from the user to set desired values of two or more parameters, which include phase characteristics and gain, for a respective band among the plurality of bands within a limit range determined based on the desired latency, and generating coefficients for the filter based on the desired values of the two or more parameters for the respective band.

### BRIEF DESCRIPTION OF THE DRAWINGS

FIG. 1 is a block diagram showing the configuration of an audio device.

FIG. 2 is a block diagram showing a main configuration of filter control.

FIG. 3 is one example of a GUI displayed on a display unit 14.

FIG. 4 is a flowchart showing the steps of a filter control process.

FIG. 5 is a flowchart showing the steps of a process for the filter coefficients.

FIG. 6 is an example of a GUI according to a modified example.

### DETAILED DESCRIPTION OF THE EMBODIMENTS

Selected embodiments will now be explained in detail below, with reference to the drawings as appropriate. It will be apparent to those skilled from this disclosure that the following descriptions of the embodiments are provided for illustration only and not for the purpose of limiting the invention as defined by the appended claims and their equivalents.

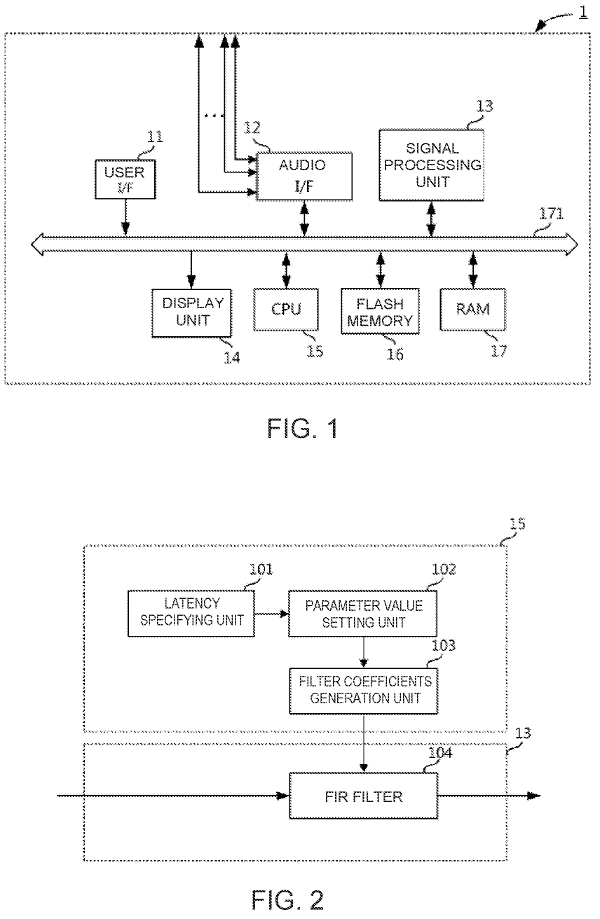

FIG. 1 is a block diagram showing the configuration of an audio device 1. The audio device 1 is an example of the filter control device which implements, as a computer, the filter control method of this disclosure. The audio device 1 is, for example, an audio mixer, an audio amplifier, a personal computer, or the like. In this embodiment, the audio device 1. as one example, will be described as an audio mixer.

The audio device 1 includes a user I/F (interface) 11, an audio I/F (interface) 12, a signal processing unit 13, a display unit 14, a CPU (Central Processing Unit) 15, a flash memory 16, and RAM (Random Access Memory) 17.

The user I/F 11 comprises a mouse or a keyboard, for example, and detects various user operations. Together with the display unit 14, the user I/F 11 can constitute a GUI (Graphical User Interface). The display unit 14 includes a display such as an LCD (Liquid Crystal Display), for example, and displays various types of information.

The CPU 15, which is one example of an electronic controller, performs various operations by reading a program from the flash memory 16, which is a storage medium, and temporarily storing the program in RAM 17. The program need not be stored in the device itself. The audio device 1 can download the required program from a server each time it is needed. The electronic controller can include one or a plurality of processors, and can be configured to comprise, instead of the CPU or in addition to the CPU. programmable logic devices such as a DSP (Digital Signal Processor), an FPGA (Field Programmable Gate Array), and the like.

The flash memory 16 and the RAM 17 are examples of one or more computer-readable devices (computer memories). The audio device 1 can include a plurality of flash memories. The audio device 1 can include a plurality of RAMs. The flash memory 16 stores the program for operating the CPU 15 as described above. Further, the flash memory 16 stores various programs for realizing a latency specifying unit 101, a parameter values setting unit 102, and a filter coefficients generation unit 103, described further below.

The audio I/F 12 acquires a sound signal via an analog audio terminal, a digital audio terminal, or a network terminal. When the audio I/F 12 acquires an analog sound signal, the sound signal is converted into a digital signal.

The signal processing unit (signal processor) 13 includes a plurality of DSPs (Digital Signal Processors) for performing various signal processes, such as mixing or effects processing, on the sound signal acquired by the audio I/F 12. The signal processing unit 13 constitutes, for example, a filter (FIR (Finite impulse response) filter) that controls the frequency characteristics of the sound signal. The filter can be realized in software in the CPU 15.

The CPU 15 generates and sets the filter coefficients of the FIR filter. FIG. 2 is a block diagram showing the main configuration of filter control. The CPU 15 is programmed to constitute the latency specifying unit 101, the parameter values setting unit 102, and the filter coefficients generation unit 103. The signal processing unit 13 constitutes an FIR filter 104.

The latency specifying unit 101 accepts an operation (specifying operation) from the user to specify a filter latency of the filter (FIR filter 104), which is detected by the user I/F 11, as a desired latency (specified latency) of the filter. The parameter values setting unit 102 accepts an operation (setting operation) from the user to set desired values of two or more parameters for a respective band among the plurality of bands within a limit range determined based on the desired latency. The filter coefficients generation unit 103 generates coefficients for the filter based on the desired values of the two or more parameters for the respective band.

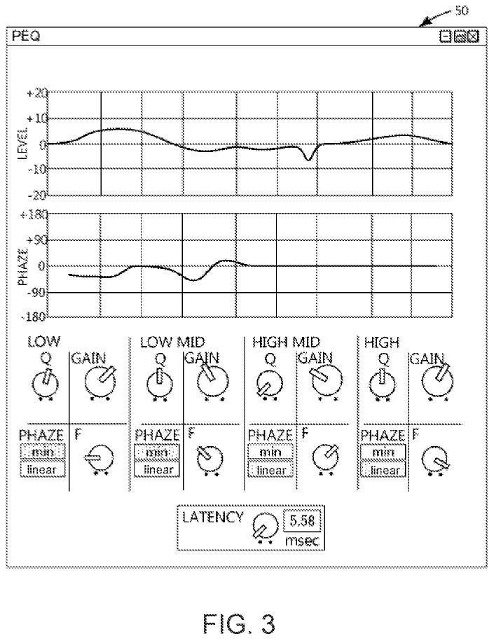

FIG. 3 shows an example of a GUI 50 displayed on the display unit 14. The GUI 50 shown in this example displays, in a graph, the frequency characteristics of the filter. The frequency characteristics include the gain characteristics and phase characteristics. Further, the GUI 50 shown in this example displays various control knobs for detecting the user operations to specify the filter latency, to adjust the frequency characteristics, and the like. The control knobs can, of course, be other types of operators, such as sliders.

The filter corresponding to this GUI 50 is, for example, a parametric equalizer (hereinafter referred to as a PEQ) that allows the user to change the frequency and Q of each band. The filter can be an equalizer that does not allow the user to change the frequency of each band, or an equalizer that does not allow the user to change the frequency and Q of each band. By the GUI 50, the user can perform an operation to specify the filter latency and set values of at least two or more parameters for the gain characteristics and phase characteristics.

The PEQ of this example allows the values of the parameters of each of four bands (LOW, LOW MID, HIGH MID, HIGH) to be set. In this disclosure, the number of bands is of course not limited to four, but can be three or fewer, or five or more.

The PEQ of this example allows the setting of the values of the following parameters: frequency (F), gain, Q factor (Q), and phase characteristics (PHAZE). In this disclosure, the number of parameters that can be set is, of course, not limited to four, but can be three: Q factor, gain, and phase characteristics: two: gain and phase characteristics; or five with the addition of type. In this example, the values of the parameters frequency (F), gain, and Q factor increase as the user rotates the respective knobs to the right and decrease as the user rotates the respective knobs to the left. The phase characteristics are selected by the user by either a linear phase (Linear) or a minimum phase (Minimum (min)) switch. If the user I/F 11 includes a touch panel, the user can touch the graph of the frequency characteristics and set the frequency characteristics by a gesture operation. For example, using two fingers, the user can perform a pinch-in or pinch-out gesture operation and, if the operation is accepted, adjust the Q factor.

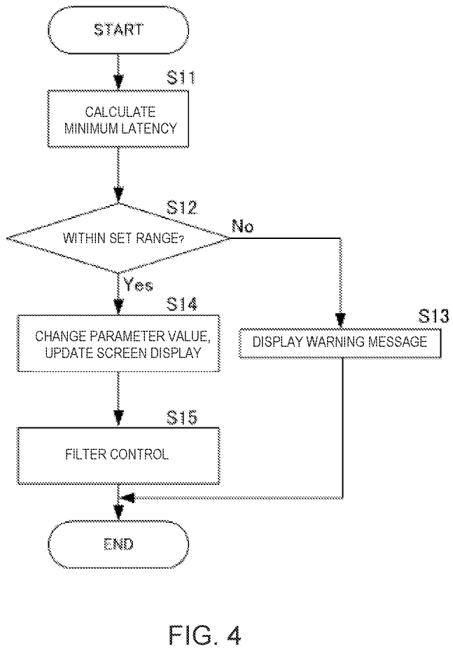

First, the latency specifying unit 101 specifies an acceptable filter latency according to an operation from the user. In the example of FIG. 3, the filter latency is specified as 5.58 msec. If the latency is set to a certain value and the user performs an operation to change the value of a parameter, the operation is detected, and the CPU 15 executes the processing steps of the flowchart shown in FIG. 4.

FIG. 4 is a flowchart showing a filter control operation. When an operation is performed to change a certain parameter in a band to a certain desired value, the CPU 15 calculates the minimum latency required to realize the frequency characteristics when the parameter is changed to the desired value (S11). The lower the frequency band, the greater the effect of each parameter on the minimum latency of the filter. For example, changing the frequency F to a lower frequency increases the minimum latency, whereas a change to a higher frequency decreases the minimum latency. If the gain is moved away from 0 dB (i.e., if the absolute value of the gain is increased), the minimum latency increases, and if the absolute value is decreased, the minimum latency decreases. If the Q factor is increased to make it narrower, the minimum latency increases, and if the Q factor is decreased to make it wider, the minimum latency decreases. Further, switching the phase characteristics to Linear increases the minimum latency, and switching the phase characteristics to Minimum decreases the minimum latency.

The CPU 15 determines whether the calculated minimum latency is within a range in which the specified latency (desired latency) (5.58 msec in the example of FIG. 3) is the upper limit (S12). If the calculated minimum latency is outside of this range defined by the specified latency, a warning is issued using the display unit 14 or the like (S13). In other words, if an operation is performed to set any of the parameters to a value that falls outside of such a latency limit range, the CPU 15 issues a warning to the user by a display, vibration, sound, etc., and terminates the operation. If the calculated minimum latency is outside of the specified latency limit range, the CPU 15 does not accept the parameter setting operation and does not change the value of the parameter. In other words, for each of a plurality of bands, the CPU 15 accepts those parameter setting operations within the limit range determined based on the specified latency and sets those parameters as the desired values.

lf the calculated latency is within the specified range, the CPU 15 sets the parameters stored in the RAM 17 as the desired values and updates the display of the frequency characteristics (S14). The CPU 15 then generates filter coefficients to be set for the FIR filter 104 based on the parameter values stored in RAM 17 (S15).

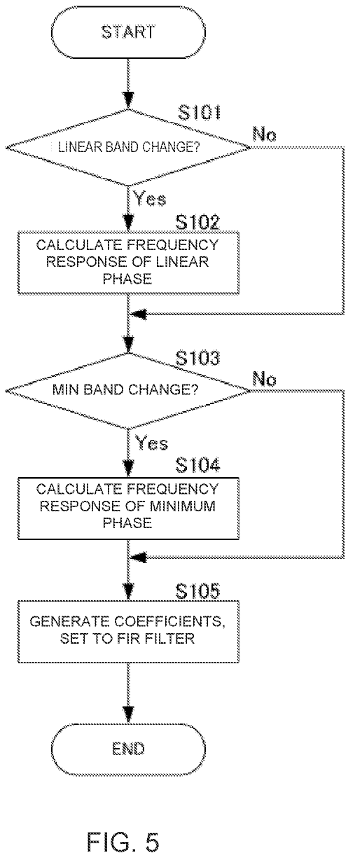

FIG. 5 is a flowchart showing the filter coefficients generation operation. The CPU 15 first calculates the frequency responses of the bands of the aforementioned four bands, for which the Linear phase characteristics and the Minimum phase characteristics have been set and then generates the filter coefficients. Each frequency response includes the amplitude response and the phase response. That is, the CPU 15 determines whether the values of any parameters have changed in any of the four bands for which the Linear phase characteristics have been set (S101). If the CPU 15 determines that the values of any parameters have changed in a band for which the Linear phase characteristics have been set, the CPU 15 calculates and stores the frequency response of the linear phase of the band for which the linear phase characteristics have been set, based on the four parameters of the band for which the linear phase characteristics have been set (S102). Further, the CPU 15 determines whether the values of any parameters have changed in a band for which the Minimum phase characteristics have been set (S103). If the CPU 15 determines that the values of any parameters have changed in a band for which the Minimum phase characteristics have been set, the CPU 15 calculates and stores the frequency response of the minimum phase of the band for which the minimum phase characteristics have been set, based on the four parameters of the band for which the minimum phase characteristics have been set (S104). The CPU 15 then generates the filter coefficients (impulse responses) corresponding to the frequency response over the entire range of the filter based on the four frequency responses stored for each of the bands and sets them in the FIR filter 104 (S105).

Moreover, the CPU 15 can generate the four impulse responses by taking the inverse Fourier transform of the frequency response of each of the four bands and convolve the four impulse responses to generate the filter coefficients. Alternatively, the CPU 15 can generate the plurality of filter coefficients by synthesizing the frequency response of each of the four bands and taking the inverse Fourier transform of the synthesized frequency responses. In this case, the frequency response to be calculated in S101 to S104 is only the amplitude response, and it is not necessary to calculate the Linear and Minimum phase responses separately. The CPU 15 calculates and stores the amplitude responses for the bands for which the value of any parameter have changed. If each amplitude response is generated on the dB scale, synthesizing the amplitude responses is a matter of simple addition. The CPU 15 synthesizes the amplitude responses for the bands set to Minimum, applies the minimum phase condition to the synthesized amplitude response to calculate the phase response for the entire band, and then adds the Linear amplitude response to the synthesized amplitude response to generate the amplitude response for the entire band. Since the phase response of the band set to Linear is always zero, the phase response for the entire band is calculated from the synthesized amplitude spectrum of the bands set to Minimum.

The frequency response for each band need not be stored in RAM 17, but can be calculated each time the filter coefficients are generated.

In the manner described above, the CPU 15 accepts the setting of the values of two or more parameters for each of a plurality of bands within a range limited in accordance with the specified latency. For example, if, with the phase characteristics of the Low band set to the minimum phase, the CPU 15 continually detects operations to increase or decrease the gain of the LOW band, the CPU 15 accepts the gain changes, and increases or decreases the gain until the gain falls outside of the gain limit range in accordance with the latency that has been specified and the phase characteristics that have been set, and once the gain is outside of this range, the CPU 15 displays a warning message and no longer accepts any further gain changes. Further, when the band is set to the linear phase, the gain limit range will be narrower still. That is, the gain limit range for a given band will vary in accordance with the specified latency and the phase characteristics that have been set for the band.

Similarly, for example, setting one parameter among frequency, phase characteristics and a gain for a band to a certain value will change the limit ranges of the other parameters in accordance with the latency specified and the value of that one parameter. For example, the lower limit (minimum limit value) of the frequency limit range of a given band will vary in accordance with the specified latency and the phase characteristics and gain set for the band. If, with the band set to the minimum phase and a gain set to a value (for example, +3 dB), the CPU 15 continually detects operations to decrease the frequency, the CPU 15 accepts the changes in frequency and lower the frequency until the frequency is below the frequency limit range: and once the frequency moves below this range, the CPU 15 displays a warning message and no longer accepts any further frequency changes. With the band set to the linear phase or with a gain farther away from 0 dB, the lower limit of the frequency limit range will be higher.

Further, the gain limit range of a certain band will vary in accordance with the specified latency, and the phase characteristics and the frequency set for the band. For example, if, with the band set to the minimum phase and a specified frequency (for example, 1 kHz), the CPU 15 continually detects operations to increase or decrease the gain, the CPU 15 accepts the gain changes and increases or decreases the gain until the gain falls outside of the gain limit range, and once the gain is outside this range, the CPU 15 displays a warning message and no longer accepts any further gain changes. With the band set to the linear phase, or at lower frequencies, the gain limit range will be narrower still.

In the example of FIG. 3, the parameters for each band include the phase characteristics, frequency, gain, and Q factor. Thus, the CPU 15 changes the limit range of the value of any one parameter, i.e., the phase characteristics, frequency, gain, or Q factor, of a given band in accordance with the specified latency and the three remaining parameters for that band. For example, if, with the band set to the minimum phase and a specified frequency (for example, 1 kHz) and gain (for example. +3 dB), he CPU 15 continually detects operations to increase (narrow) the Q factor of a given band, the CPU 15 accepts the changes in Q factor and increases the Q factor until the upper limit of that limit range is exceeded, at which time a wanting message will be displayed and no further changes in Q factor will be accepted. With the band set to the linear phase, a lower frequency, or a gain farther away from 0 dB, the upper limit of the Q factor limit range will be lower still.

Further, setting the phase characteristics of a certain band to the minimum phase decreases the minimum latency, so that the setting operation is always accepted. On the other hand, changing the setting from the minimum phase to the linear phase increases the minimum latency; thus, if the minimum latency is smaller than the specified latency when the setting is changed to the linear phase, the setting change will be accepted and the phase characteristics of the aforementioned band will be changed to the linear phase. In other words, while the CPU 15 (parameter value setting unit 102) always accepts one or more operations to set the phase characteristics to the minimum phase, the CPU 15 accepts one or more operations to set the phase characteristics to the linear phase when the latency and a parameter of the two or more parameters other than the phase characteristics satisfy a first condition.

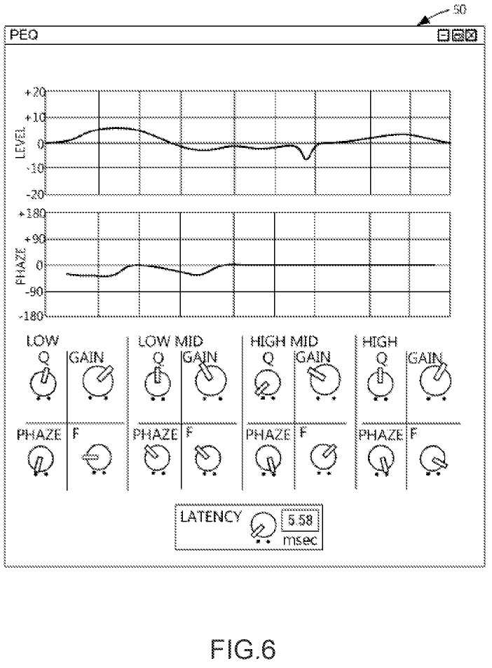

Next, FIG. 6 shows one example of a GUI 50 according to a modified example. In the modified example, the GUI 50 detects an operation to set intermediate characteristics (intermediate phase), from the minimum phase to the linear phase of the phase characteristics. In the example of FIG. 6, the CPU 15 displays knobs for detecting the user operations to set the phase characteristics. The user, by operations of rotating the knobs of each band, performs an operation to set the intermediate phase in a range from the minimum phase to the linear phase of the phase characteristics of each band. When the user rotates a phase characteristics knob (PHAZE) to the right, an operation to bring the phase characteristics closer to the linear phase is detected, and when this knob is rotated to the left, an operation to bring the phase characteristics closer to the minimum phase is detected. The phase characteristics are linear when the knob is turned completely to the right, and minimal when turned to completely the left.

Operations that change the phase characteristics of a band from the linear phase to the intermediate phase are always accepted since such operations decrease the minimum latency. On the other hand, operations that change from the minimum phase to the intermediate phase increase the minimum latency; thus, if the minimum latency calculated when the phase characteristics are changed is smaller than the specified latency, it is accepted, and the phase characteristics are set to that intermediate phase. In other words, the CPU 15 (parameter value setting unit 102) always accepts one or more operations to change the phase characteristics from the linear phase to the intermediate phase, whereas the CPU 15 accepts one or more operations to change the phase characteristics from the minimum phase to the intermediate phase when the latency, and a parameter of the two or more parameters other than the phase characteristics satisfy a second condition. Here, if the user continuously rotates the phase characteristics knob of a certain band to the right, the phase characteristics of the band will gradually approach the linear phase and eventually the knob will stop moving when the latency limit range is exceeded.

As described above, in the audio device of the present embodiment, when one parameter is set with the latency specified, the range over which the values of the other parameters can be set is constrained by this one parameter. This allows the user of the audio device of the present embodiment to adjust the value of the parameter within the acceptable latency range. For example, the user operates the GUI first to set the phase characteristics of all bands to the minimum phase and specify the acceptable latency, and then to set the frequency response (gain, frequency, and Q factor) to generate the sound. The user then changes the phase characteristics of the desired band to the linear phase and compares the sounds before and after the phase change. For example, the frequency response (amplitude and phase characteristics) of the sound that is output from the speaker changes due to the audio transmission characteristics of the room. After adjusting the amplitude response, the user switches the phase characteristics of the desired band between the linear phase and the minimum phase, listening to the influence of the audio transmission characteristics of the room on the sound, and selects one of the phase characteristics. During this process, the user can adjust the phase characteristics within the specified latency range. This allows the user to determine whether the linear phase or the minimum phase is better for each band within the range satisfying the desired latency.

The user can, for example, perform an operation to change the latency to another value after setting the frequency response and generating the sound. In this case, the CPU 15 can accept the operation and specify that latency value, and automatically change the setting of each band to the minimum phase or the linear phase, so that the minimum latency calculated from the set frequency response falls within the specified latency range.

Moreover, in the embodiment described above, the CPU 15 issues a warning when an operation is performed to set any parameter of a band to a value that falls outside of the latency limit range and terminates the operation without setting the value. However, instead of issuing a wanting, the CPU 15 can instead accept the setting, set the parameter to that value, and adjust the other parameters of that band (e.g., change the phase characteristics to the minimum phase, or bring it closer to the minimum phase, etc.) to remain within the latency limit range.

The description of this embodiment should be considered in all respects illustrative and not restrictive. The scope of this disclosure is indicated by the claims section, and not by the embodiment described above. Furthermore, the scope of this disclosure includes the scope that is equivalent that of the Claims.

For example, the filter of this embodiment is not limited to a PEQ, and can be a graphic equalizer. In the graphic equalizer, the latency specification is accepted and the gain and phase characteristics settings are accepted for each frequency.

By this disclosure, the values of the parameters can be adjusted within an acceptable latency range.

What is claimed is:

1. A filter control method for controlling a filter that controls frequency characteristics of a sound signal over a plurality of bands, the filter control method being implemented by a computer, the filter control method comprising:
accepting a specifying operation from a user to specify a latency of the filter as a desired latency of the filter;
accepting a setting operation from the user to set desired values of two or more parameters for a respective band among the plurality of bands within a limit range determined based on the desired latency, the two or more parameters including phase characteristics and gain; and
generating coefficients for the filter based on the desired values of the two or more parameters for the respective band.

2. The filter control method according to claim 1, wherein
the limit range includes a value range of the gain which changes in accordance with the desired latency and the phase characteristics.

3. The filter control method according to claim 1, wherein
the two or more parameters further include a frequency for each band,
the limit range includes a lower limit of the frequency which changes in accordance with the desired latency, the phase characteristics, and the gain, and
the limit range includes a value range of the gain which changes in accordance with the desired latency, the phase characteristics, and the frequency.

4. The filter control method according to claim 1, wherein
the two or more parameters further include a frequency and a Q factor for each band, and
the limit range includes a value range of one parameter of the phase characteristics, the frequency, the gain, and the Q factor, and the value range changes in accordance with the desired latency and remaining three parameters other than the one parameter.

5. The filter control method according to claim 1, further comprising issuing a warning to the user when determining that any one of the desired values set in response to the setting operation from the user is outside of the limit range.

6. The filter control method according to claim 1, wherein
in the accepting of the setting operation, a first setting operation to set the phase characteristics to a minimum phase from the user is always accepted, whereas a second setting operation to set the phase characteristics to a linear phase from the user is accepted in a first case where the desired latency and a parameter of the two or more parameters other than the phase characteristics satisfy a first condition.

7. The filter control method according to claim 6, wherein
in the accepting of the set operation, a third setting operation to set the phase characteristics from the linear phase to an intermediate phase from the user is always accepted, whereas a fourth setting operation to set the phase characteristics from the minimum phase to the intermediate phase from the user is accepted in a second case where the desired latency and a parameter of the two or more parameters other than the phase characteristics satisfy a second condition.

8. A filter control device for controlling a filter that controls frequency characteristics of a sound signal over a plurality of bands, the filter control device comprising:
one or more processors; and
one or more computer-readable devices storing instructions that, when executed by the one or more processors, cause the one or more processors to perform
accepting a specifying operation from a user to specify a latency of the filter as a desired latency of the filter,
accepting a setting operation from the user to set desired values of two or more parameters for a respective band among the plurality of bands within a limit range determined based on the desired latency, the two or more parameters including phase characteristics and gain, and
generating coefficients for the filter based on the desired values of the two or more parameters for the respective band.

9. The filter control device according to claim 8, wherein
the limit range includes a value range of the gain which changes in accordance with the desired latency and the phase characteristics.

10. The filter control device according to claim 8, wherein
the two or more parameters further include a frequency for each band,
the limit range includes a lower limit of the frequency which changes in accordance with the desired latency, the phase characteristics, and the gain, and
the limit range includes a value range of the gain which changes in accordance with the desired latency, the phase characteristics, and the frequency.

11. The filter control device according to claim 8,wherein
the two or more parameters further include a frequency and a Q factor for each band, and
the limit range includes a value range of one parameter of the phase characteristics, the frequency, the gain, and the Q factor, and the value range changes in accordance with the desired latency and remaining three parameters other than the one parameter.

12. The filter control device according to claim 8, wherein
the instructions cause the one or more processors to further perform issuing a warning to the user when determining that any one of the desired values set in response to the setting operation from the user is outside of the limit range.

13. The filter control device according to claim 8, wherein
in the accepting of the setting operation, a first setting operation to set the phase characteristics to a minimum phase from the user is always accepted, whereas a second setting operation to set the phase characteristics to a linear phase from the user is accepted in a first case where the desired latency and a parameter of the two or more parameters other than the phase characteristics satisfy a first condition.

14. The filter control device according to claim 13, wherein
in the accepting of the set operation, a third setting operation to set the phase characteristics from the linear phase to an intermediate phase from the user is always accepted, whereas a fourth setting operation to set the phase characteristics from the minimum phase to the intermediate phase from the user is accepted in a second case where the desired latency and a parameter of the two or more parameters other than the phase characteristics satisfy a second condition.
